(19) United States
(12) Patent Application Publication
(10) Pub. No.: US 2010/0083902 A1
(43) Pub. Date: Apr. 8, 2010

(54) Plasma generating device

(75) Inventors: Su Hong Kim, Yongin-si (KR); Myoung Soo Park, Seoul (KR); Sung Keun Cho, Seoul (KR); Doug Yong Sung, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,686

(22) Filed: Sep. 22, 2009

(30) Foreign Application Priority Data
Oct. 2, 2008 (KR) 10-2008-0097020

(51) Int. Cl. C23C 16/513

(52) U.S. Cl. 118/723 R

(57) ABSTRACT

A plasma generating device is disclosed, which generates plasma by supplying a bias RF power in the initial state in an inductive coupled plasma (ICP) system. Especially, an insulator which insulates a ground member from a susceptor supplied with the bias RF power is separated into at least two pieces such that the thermal expansion of the insulator can be generated similarly to adjoining parts.

### CROSS-REFERENCE TO RELATED APPLICATION(S)

This application claims priority under 35 U.S.C. §119 to Korean Patent Application No. 10-2008-0097020, filed on Oct. 2, 2008, in the Korean Intellectual Property Office (KIPO), the entire contents of which are herein incorporated by reference.

### BACKGROUND

1. Field

Example embodiments relate to a plasma generating device, and more particularly to an insulator which insulates an electrode and a ground from each other in an inductively coupled plasma generating device.

2. Description of the Related Art

Chemical vapor deposition (CVD) methods may be used to fabricate liquid crystal display (LCD) substrates and semiconductor substrates. A CVD method may have relatively excellent uniformity and step coverage. An example of a CVD method is a plasma enhanced CVD (PECVD) method. The PECVD method enables relatively low-temperature vapor deposition and relatively high-speed thin film formation.

The PECVD method may be divided into a method using a capacitively coupled plasma (CCP) and a method using an inductively coupled plasma (ICP). The former method applies a radio frequency (RF) power to a plasma electrode, and the latter applies an RF power to an induction coil and utilizes an induced magnetic field generated from the induction coil.

The CCP method is capable of generating relatively high-energy ions using a relatively high magnetic field, and therefore is appropriate for removing a film, for example, a silicon dioxide film. However, according to the CCP method, the ions have such high energy that a CVD process and a sputtering process cannot be simultaneously performed at a low pressure.

The ICP method makes a relatively low energy distribution of ions while having a relatively high plasma density. Therefore, the ICP method is advantageous in terms of a relatively high efficiency in processing the substrate and a relatively low damage risk of the substrate during etching. However, according to the ICP method, density of the ions of a plasma gas generated in a chamber is uniform only in the center part of the chamber but becomes irregular toward the peripheral part.

### SUMMARY

Example embodiments provide an inductively coupled plasma generating device which is improved in the thermal expansion property of an insulator that insulates an electrode and a ground member from each other.

Example embodiments will be set forth in part in the description which follows and, in part, will be obvious from the description, or may be learned by practice of the invention.

In accordance with example embodiments, a plasma generating device may include a chamber, a susceptor configured to support a substrate and receive power while supporting the substrate, a support base supported by the chamber, the support base being configured to support the susceptor, and an insulator between the susceptor and the support base to insulate the susceptor and the support base from each other, wherein the insulator includes at least two pieces.

In accordance with example embodiments, a plasma generating device may include a chamber, a susceptor configured to support a substrate and receive power while supporting the substrate, a support base supported by the chamber, the support base being configured to support the susceptor, and an insulator between the susceptor and the support base to insulate the susceptor and the support base from each other, wherein the insulator has at least one sectional plane therein.

In accordance with example embodiments, a plasma generating device may include a chamber, a susceptor configured to support a substrate and receive power while supporting the substrate, a support base supported by the chamber, the support base being configured to support the susceptor, and an insulator between the susceptor and the support base to insulate the susceptor. and the support base from each other, wherein the insulator maintains a thermal strain, induced by temperature variations, that is substantially the same as a thermal strain of at least one of the susceptor and the support base.

In accordance with example embodiments, a plasma generating device may include a chamber which receives a substrate, a susceptor applied with power while supporting the substrate, a support base supporting the susceptor, being supported by the chamber, and an insulator disposed between the susceptor and the support base to insulate the susceptor and the support base from each other, wherein the insulator is divided into at least two pieces.

The insulator may include a first insulator and a second insulator, and an interface between the first and second insulators may be in the form of an uneven surface including a prominence and a depression.

The insulator may be made of ceramic or engineering plastic.

The ceramic may contain Al₂O₃ or AlN.

The engineering plastic may contain polyether ether ketone (PEEK) resin, Ultem, or Teflon.

A vacuum space may be formed between the support base and the chamber.

The support base and the chamber may be connected by a communication member which may fluidly communicate an inside of the support base with an outside of the chamber.

In accordance with example embodiments, a plasma generating device may include a chamber which receives a substrate, a susceptor applied with power while supporting the substrate, a support base supporting the susceptor, being supported by the chamber, and an insulator disposed between the susceptor and the support base to insulate the susceptor and the support base from each other, wherein the insulator has at least one sectional plane therein.

The sectional plane may be an uneven surface including a prominence and a depression.

In accordance with example embodiments, a plasma generating device may include a chamber which receives a substrate, a susceptor applied with power while supporting the substrate, a support base supporting the susceptor, being supported by the chamber, and an insulator disposed between the susceptor and the support base to insulate the susceptor and the support base from each other, wherein the insulator maintains the thermal strain determined by temperature variations, similar to the thermal strain of the susceptor or the support base.

The insulator may be divided into at least two pieces.

The insulator may be made of a material having a similar thermal expansion coefficient to a material of the susceptor or the support base.

Thus, according to example embodiments, damage of the insulator may be prevented or reduced, accordingly preventing or reducing a generation of arcing.

Furthermore, reliability of the product may be improved by securely maintaining the inside of the chamber under vacuum.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIG. 1 schematically shows the structure of a plasma generating device according to example embodiments;

FIGS. 2A-2B show a rectangular insulator of the plasma generating device including at least two separate pieces and an interface between the at least two separate pieces includes a prominence and a depression according to example embodiments;

FIG. 2C shows a rectangular insulator of the plasma generating device including at least two separate pieces and an interface between the at least two separate pieces includes a stepped shape according to example embodiments;

FIG. 2D shows a rectangular insulator of the plasma generating device including at least two separate pieces and an interface between the at least two separate pieces includes a jagged shape according to example embodiments;

FIG. 2E shows a rectangular insulator of the plasma generating device including at least two separate pieces and an interface between the at least two separate pieces is vertical;

FIGS. 3A-3B show a circular insulator of the plasma generating device including at least two separate pieces and an interface between the at least two separate pieces includes a stepped shape according to example embodiments;

FIG. 3C shows an alternative section view of a circular insulator according to example embodiments; and

FIG. 4 illustrates a sealing structure of the plasma generating device according to example embodiments.

### DETAILED DESCRIPTION OF EXAMPLE EMBODIMENTS

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the, spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

Reference will now be made in detail to example embodiments, examples of which are illustrated in the accompanying drawings, wherein like reference numerals refer to the like elements throughout. Example embodiments are described below by referring to the figures.

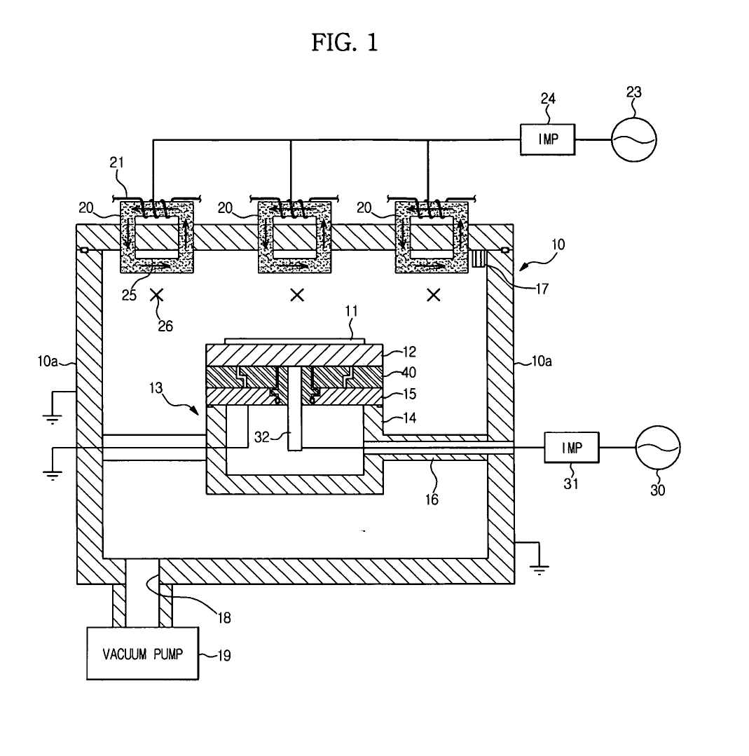

FIG. 1 schematically shows the structure of a plasma generating device according to example embodiments.

As shown in FIG. 1, the plasma generating device of example embodiments may include a chamber 10 having a predetermined or preset capacity, a susceptor 12 supporting a substrate 11 within the chamber 10, and a support base 13 supporting the susceptor 12. The susceptor 12 may include a heater capable of heating up the substrate 11. The chamber 10 may include a vent hole 18. As a vacuum pump 19 operates, air may be discharged through the vent hole 18 so that a space between the support base 13 and the chamber 10 is vacuumized. The support base 13 may include a base body 14 opened upward and a ground member 15 sealing the opened upper part. The support base 13 may be fluidly communicated with the outside of the chamber 10 through a communication member 16. The inside of the support base 13 may be maintained under atmospheric pressure.

A ferrite core 20 may be in an upper part of the chamber 10, and wound with an induction coil 21. A source RF generator 23 may apply RF power to the induction coil 21. In addition, a source impedance matching box 24 may be connected to the source RF generator 23 so as to correspond a load impedance to a characteristic impedance of a connection cable connected with the source RF generator 23.

An RF transmission member 32 may be provided in the chamber 10 to apply RF bias power to the susceptor 12. The RF transmission member 32 may be connected to a bias RF generator 30 through a connection cable. Also, a bias impedance matching box 31 may be connected to correspond to a load impedance to a characteristic impedance of the connection cable connected with the bias RF generator 30.

A reactive gas may be injected to the vacuum space in the chamber 10 through a gas supplying pipe 17 that may be formed at an upper part of the chamber 10. The induction coil 21 may be applied with the RF power supplied from the source RF generator 23 passing through the source impedance matching box 24. An induced magnetic field 25 may, therefore, be produced at an upper space of the susceptor 12 by the induction coil 21 and the ferrite core 20. Because the induced magnetic field 25 is sort of a time-varying magnetic field, an induced electric field 26 may be generated perpendicularly to the induced magnetic field 25. Plasma may be generated as electrons accelerated by the induced electric field 26 collide with ambient neutral gas. A method that generates the plasma through an induced magnetic field 25 and an induced electric field 26 is referred to as an inductively coupled plasma (ICP) method.

According to the ICP method, however, it may be difficult to initially generate the plasma because relatively low-energy ions may be generated. That is, at the initial state, plasma may be hard to generate in the chamber 10 even though a source RF voltage is applied from the source RF generator 23 to the induction coil 21. In example embodiments, the initial state means a state where plasma is not yet generated in the chamber 10.

Therefore, a bias RF voltage may be applied to the susceptor 12 so as to generate plasma in the chamber 10 in the initial state. The RF transmission member 32 may be mounted at a lower pail of the susceptor 12, and the bias RF voltage supplied from the bias RF generator 30 may be applied to the susceptor 12 through the RF transmission member 32. Because a sidewall 10a of the chamber 10 is grounded, a relatively high electric field may be generated between the susceptor 12 and the sidewall 10a. Accordingly, relatively high-energy ions may be generated by the relatively high electric field, and plasma may be produced in the chamber in the initial state.

In other words, the bias RF voltage may be supplied to the susceptor 12 in the initial state, thereby generating the plasma in the chamber 10 and the source RF voltage may be supplied to the induction coil 21 so that the plasma may be continuously generated in the chamber 10. The plasma thus generated by the ICP method may have a relatively high density, accordingly achieving a relatively high efficiency in processing the substrate may be achieved. Furthermore, the relatively low energy may reduce or eliminate a risk of damage to the substrate.

The susceptor 12 may be supported by the ground member 15, and an insulator 40 may be disposed between the susceptor 12 and the ground member 15 to prevent or reduce the generation of plasma between the susceptor 12 and the ground member 15. Because the susceptor 12 may be supplied with the RF power and the ground member 15 may be grounded, if a space exists between the susceptor 12 and the ground member 15, plasma may be generated in that space. Plasma, however, needs to be generated at an upper part of the susceptor 12 for processing of the susceptor 12. However, the plasma may be difficult to generate at the upper part of the susceptor 12 if plasma were generated between the susceptor 12 and the ground member 15.

Furthermore, in a case where the susceptor 12 and the ground member 15 are in direct connection with each other, arcing may occur due to a voltage difference between the susceptor 12 and the ground member 15. This may hinder generation of the electric field in the chamber 10.

The insulator 40 may be disposed between the susceptor 12 and the ground member 15, and may be connected with the susceptor 12 and the ground member 15 using bolts B.

The insulator 40 may be made of ceramic. For example, the insulator 40 may be made of a ceramic that includes Al₂O₃ and/or AlN. The insulator 40, however, is not limited to the above materials, for example, the insulator 40 may be made from engineering plastic comprising polyether ether ketone (PEEK) resin, Ultem, and/or Teflon. The susceptor 12 and the ground member 15 may be made of a different material from the insulator 40, for example, metal. Because the insulator 40, the ground member 15, and the susceptor 12 may be made from different materials, the insulator 40, the susceptor 12 and the ground member 15 may have different thermal expansion coefficients from one another.

An ambient temperature of T1 when the insulator 40 is connected between the susceptor 12 and the ground member 15 may be different from an ambient temperature of T2 when the plasma is generated in the chamber 10 and the process is being performed. As the ambient temperature varies between the temperatures T1 and T2, the susceptor 12 and the insulator 40 may be thermally deformed. Because a thermal expansion coefficient α1 of the susceptor 12 and a thermal expansion coefficients α2 of the insulator 40 may be different from each other, thermal strains S of the susceptor 12 and of the insulator 40 may become different. The thermal strain S may be defined as follows:

S=αLΔT

(S: thermal strain, α: thermal expansion coefficient, L: length, ΔT=(T2−T1): temperature variation)

Owing to such a difference of the thermal strains S between the susceptor 12 and the insulator 40, the insulator 40 may be damaged. Accordingly, the vacuum state of the inside of the chamber 10 may not be securely maintained. Also, arcing may be generated. Damage to the insulator 40 may be reduced or prevented if the thermal strain S2 of the insulator 40 was almost the same as the thermal strain S1 of the susceptor 12.

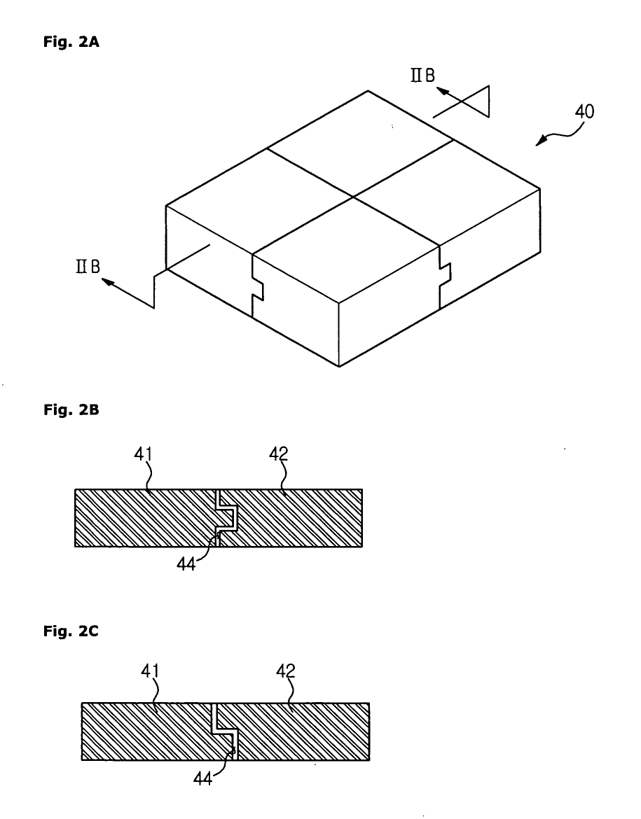

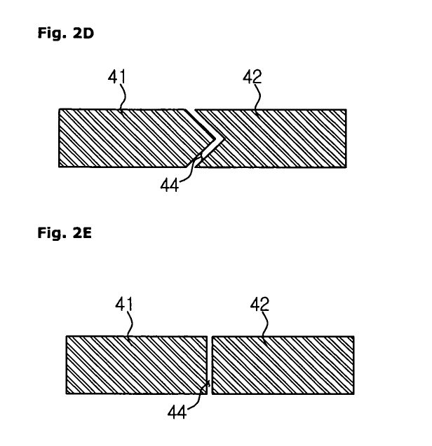

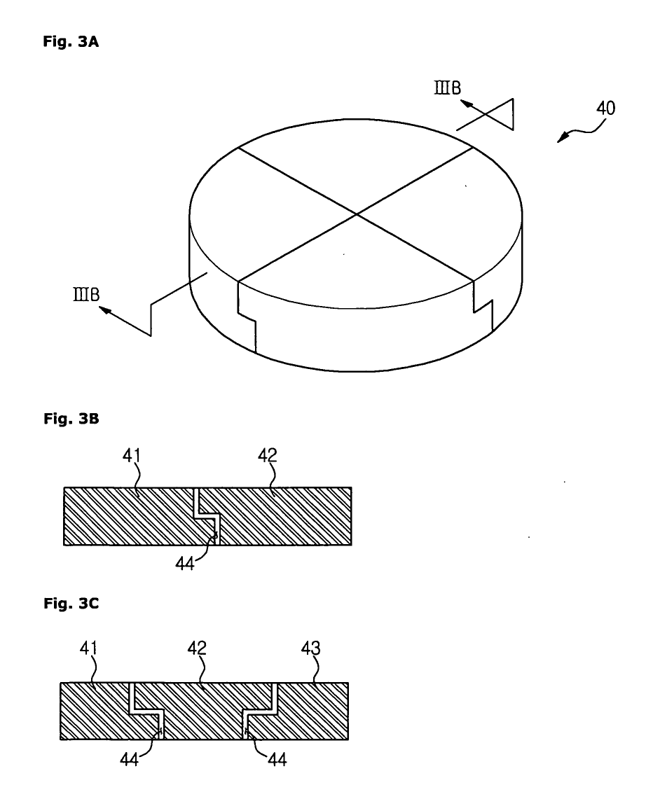

FIGS. 2A-2E and FIGS. 3A-3C are views showing the insulator according to example embodiments.

Referring to FIGS. 2A and 3A, the insulator 40 according to example embodiments may have a rectangular or circular form. FIG. 2B represents a section view of the insulator 40 shown in FIG. 2A taken through section line IIB-IIB of FIG. 2A. FIG. 3B represents a section view of the insulator 40 shown in FIG. 3A taken through section line IIIB-IIIB of FIG. 3A.

As shown in FIG. 2B, the insulator 40 illustrated in FIG. 2A may be constituted by at least two separate pieces: a first insulator 41; and a second insulator 42. An interface 44 between the first and the second insulators 41 and 42 may be in the form of an uneven surface including a prominence and a depression as shown in FIG. 2B, however, example embodiments are not limited thereto. For example, the interface 44 may have a stepwise form as shown in FIG. 2C or a jagged form as shown in FIG. 2D. However, a mere vertical plane as shown in FIG. 2E is not recommended for the shape of the interface 44 because problems, for example, arcing, may occur due to the voltage difference between the susceptor 12 and the ground member 15.

FIG. 3B shows a sectional shape of the insulator 40 illustrated in FIG. 3A cut along section line IIIB-IIIB. Although FIGS. 3A and 3B illustrate a circular insulator 40 having a cross-section with two members, example embodiments are not limited thereto. For example, insulator 40 may also be divided in the manner as shown in FIG. 3B.

By thus separating the insulator 40 into several pieces, the thermal strain S2 of the insulator 40 with respect to a length L2 of the insulator 40 may be reduced. More specifically, for example, in a case where the thermal expansion coefficient α2 of the insulator 40 is twice as large as the thermal expansion coefficient α1 of the susceptor 12, when the length L2 of the insulator 40 is set to a half of a length L1 of the susceptor 12, the thermal strain S1 of the susceptor 12 and the thermal strain S2 of the insulator 40 may be defined as below.

S1=(α1)(L1)(ΔT)

S2=(α2)(L2)(ΔT)=(α1)(L1)(ΔT)

Because the thermal strains S1 and S2 may become about the same, the thermal deformation of the susceptor 12 and the insulator 40 according to the temperature variation ΔT may be about the same. As a result, the insulator 40 may be securely connected between the susceptor 12 and the ground member 15.

As aforementioned, the insulator 40 and the susceptor 12 may be connected by the bolts B. Distances among the bolts B may be shortened in each piece of the insulator 40, thereby causing change of the thermal strain S. That is, the thermal strains S of the insulator 40 and the susceptor 12 may be equalized by separating the insulator 40 into at least two pieces. Consequently, damage of the insulator 40 may be prevented or reduced in spite of variation of the ambient temperatures T1 and T2.

Referring to the above explanation about the thermal strains S of the susceptor 12 and the insulator 40, damage caused by a difference of thermal strains between the ground member 15 and the insulator 40 may also be solved in the same manner.

Furthermore, the insulator 40 may be made of a material having a property that is similar to a property of the material of the susceptor 12 or the ground member 15. For example, the insulator 40 may have a thermal expansion coefficient α similar to, or substantially the same as, the thermal expansion coefficient α of the susceptor 12 or the ground member 15. Accordingly, the insulator 40 may have a thermal strain S which is similar to, or substantially the same as, a thermal strain of the susceptor 12 or the ground member 15. In this case, however, the insulator 40 may need to have a length L that is similar to, or substantially the same as, the length of the susceptor 12 or the ground member 15.

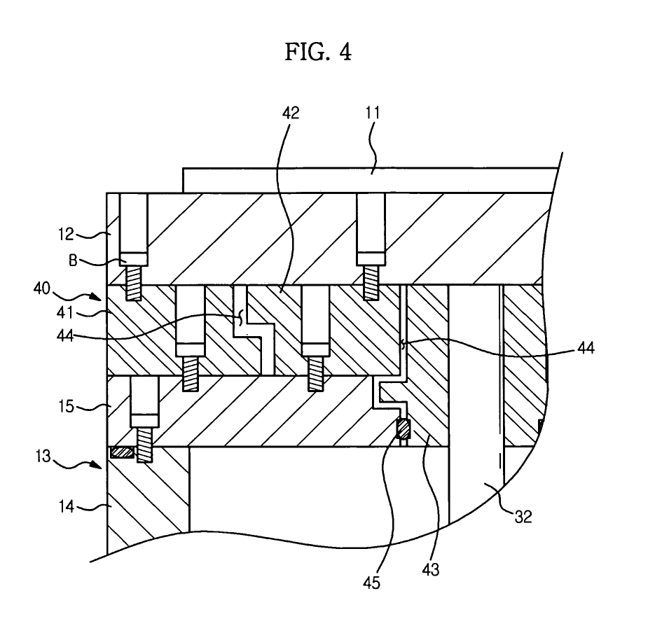

FIG. 4 shows a sealing structure of the plasma generating device according to example embodiments.

Referring to FIG. 4, the insulator 40 includes first to third insulators 41, 42 and 43. The interface 44 between the first and the second insulators 41 and 42 has a stepwise form. The interfaces 44 among the second insulator 42, the third insulator 43 and the ground member 15 are in the form of an uneven surface.

Because the insulator 40 may be separated into the first, second and third insulators 41, 42 and 43, a sealing member 45 may be inserted between the third insulator 43 and the ground member 15 so that the vacuum state in the chamber 10 may be maintained. The sealing member 45 may include an O-ring. If the sealing is performed with all the interfaces 44 among the insulators 41, 42 and 43, the sealing structure becomes complicated and the sealing effect may be deteriorated by the thermal expansion of the insulator 40.

By thus separating the insulator 40 into several pieces, damage of the insulator 40 by the temperature variation may be prevented or reduced. Also, the inside of the chamber 10 may be maintained under the vacuum state by additionally forming the sealing member 45 between the insulator 40 and the ground member 15.

While example embodiments have been particularly shown and described with reference to example embodiments thereof, it will be understood by those of ordinary skill in the art that various changes in form and details may be made therein without departing from the spirit and scope of the following claims.

What is claimed is:

1. A plasma generating device comprising:
a chamber;
a susceptor configured to support a substrate and receive power while supporting the substrate;
a support base supported by the chamber, the support base being configured to support the susceptor; and
an insulator between the susceptor and the support base to insulate the susceptor and the support base from each other,
wherein the insulator includes at least two pieces.

2. The plasma generating device according to claim 1, wherein the insulator includes a first insulator and a second insulator, and an interface between the first and second insulators is an uneven surface including a prominence and a depression.

3. The plasma generating device according to claim 1, wherein the insulator is made of at least one of a ceramic and an engineering plastic.

4. The plasma generating device according to claim 3, wherein the ceramic contains at least one of Al₂O₃ and AlN.

5. The plasma generating device according to claim 3, wherein the engineering plastic contains at least one of polyether ether ketone (PEEK) resin, Ultem, and Teflon.

6. The plasma generating device according to claim 1, wherein a vacuum space is between the support base and the chamber.

7. The plasma generating device according to claim 6, wherein the support base and the chamber are connected by a communication member which fluidly communicates an inside of the support base with an outside of the chamber.

8. A plasma generating device comprising:
a chamber;
a susceptor configured to support a substrate and receive power while supporting the substrate;
a support base supported by the chamber, the support base being configured to support the susceptor; and
an insulator between the susceptor and the support base to insulate the susceptor and the support base from each other,
wherein the insulator has at least one sectional plane therein.

9. The plasma generating device according to claim 8, wherein the at least one sectional plane is an uneven surface including a prominence and a depression.

10. A plasma generating device comprising:
a chamber;
a susceptor configured to support a substrate and receive power while supporting the substrate;
a support base supported by the chamber, the support base being configured to support the susceptor; and
an insulator between the susceptor and the support base to insulate the susceptor and the support base from each other,
wherein the insulator maintains a thermal strain, induced by temperature variations, that is substantially the same as a thermal strain of at least one of the susceptor and the support base.

11. The plasma generating device according to claim 10, wherein the insulator includes at least two pieces.

12. The plasma generating device according to claim 10, wherein the insulator and at least one of the susceptor and the support base are made of materials having substantially the same thermal expansion coefficients.
